(19) United States
(12) Patent Application Publication
(10) Pub. No.: US 2026/0250831 A1
(43) Pub. Date: Aug. 27, 2026

(54) LINEAR DEPOSITION SOURCE AND ELECTRONIC DEVICE

(71) Applicant: Samsung Display Co., LTD., Yongin-si (KR)

(72) Inventors: DONGKIUN SEO, Yongin-si (KR); SANGMIN JUNG, Yongin-si (KR); HWAPYEONG JEONG, Yongin-si (KR); JONGGUN YUN, Yongin-si (KR); KYOUNGWOON LEE, Yongin-si (KR)

(21) Appl. No.: 19/448,577

(22) Filed: Jan. 14, 2026

(30) Foreign Application Priority Data
Feb. 27, 2025 (KR) 10-2025-0025759
May 2, 2025 (KR) 10-2025-0058404

(51) Int. Cl. C23C 14/24; C23C 14/04

(52) U.S. Cl. CPC C23C 14/243; C23C 14/042

(57) ABSTRACT

A linear deposition source includes a crucible that extends in a first direction and accommodates a deposition material in an inner space thereof, a plurality of nozzles disposed on the crucible and arranged in the first direction, a heater frame that accommodates the crucible and in which a plurality of first openings and a plurality of second openings arranged in the first direction are defined, a plurality of heaters disposed between the heater frame and the crucible, a radiant heat preventing member that accommodates the heater frame, and a housing that accommodates the radiant heat preventing member. Each of the heaters includes a first insulator, a heating element including a heater pattern disposed on the first insulator and an electrode part connecting to one end of the heater pattern and passing through the first openings, a second insulator covering the electrode part, and a third insulator covering the heater pattern.

### CROSS-REFERENCE TO RELATED APPLICATIONS

This application claims priority to Korean Patent Application No. 10-2025-0025759, filed on February 27, 2025, and Korean Patent Application No. 10-2025-0058404, filed on May 02, 2025, and all the benefits accruing therefrom under 35 U.S.C. § 119, the contents of which in their entirety are incorporated herein by reference.

### BACKGROUND

Embodiments of the present disclosure described herein relate to a linear deposition source, and more particularly, relate to a linear deposition source used in a deposition device.

Embodiments of the present disclosure described herein relate to an electronic device including a substrate manufactured by a linear deposition source.

A display device may include a light emitting layer between electrodes facing each other. One of various methods of forming the electrodes is a deposition method using a deposition device. The electrodes may include a metallic material, and a deposition device in a high-temperature environment may be used to deposit the metallic material on a substrate.

### SUMMARY

Embodiments of the present disclosure provide a linear deposition source including a heater and a heater frame for reducing condensation of a deposition material.

Embodiments of the present disclosure provide an electronic device including a substrate manufactured by a linear deposition source including a heater and a heater frame for reducing condensation of a deposition material.

According to an embodiment, a linear deposition source includes a crucible that extends in a first direction and accommodates a deposition material in an inner space thereof, a plurality of nozzles disposed on the crucible and arranged in the first direction, a heater frame that accommodates the crucible and in which a plurality of first openings and a plurality of second openings arranged in the first direction are defined, a plurality of heaters disposed between the heater frame and the crucible, a radiant heat preventing member that accommodates the heater frame, and a housing that accommodates the radiant heat preventing member. Each of the heaters includes a first insulator, a heating element including a heater pattern disposed on the first insulator and an electrode part that is connected to one end of the heater pattern and that passes through the first openings, a second insulator that covers the electrode part, and a third insulator that covers the heater pattern.

The electrode part may include a connecting part that connects an external electrode disposed outside the housing and the heater pattern and a fastening part connected to the one end of the heater pattern.

The fastening part may include a connecting member that connects the heater pattern and the connecting part.

The one end of the heater pattern may be closer to the nozzles than the first openings in a third direction crossing both the first direction and a second direction crossing the first direction.

The first insulator may have a plate shape, the second insulator may have a pipe shape, and the third insulator may have a plate shape.

The heaters may be disposed along an inside surface of the heater frame and may be independently controllable.

The heaters may include a first heater, a second heater arranged together with the first heater in the first direction, a third heater arranged together with the first heater in a third direction crossing both the first direction and a second direction crossing the first direction, and a fourth heater arranged together with the third heater in the first direction.

The linear deposition source may further include a fifth insulator disposed on the first heater, the second heater, the third heater, and the fourth heater.

The linear deposition source may further include a fourth-first insulator disposed on the first heater and the second heater and a fourth-second insulator disposed on the third heater and the fourth heater.

The fourth-first insulator and the fourth-second insulator may be disposed on the heater pattern, the electrode part, and the second insulator.

The linear deposition source may further include a sixth insulator that covers the second insulator and that is disposed under the fourth-first insulator or the fourth-second insulator.

The linear deposition source may further include a plurality of covers movable above the second openings in a third direction crossing both the first direction and a second direction crossing the first direction.

The linear deposition source may further include a camera that is disposed outside the heater frame and that takes an image of the inside of the heater frame through the second openings.

The linear deposition source may further include a cooling device disposed on the housing. The cooling device may include a cooling pipe through which cooling water flows, and the radiant heat preventing member may make contact with the cooling device.

According to an embodiment, a linear deposition source includes a crucible that extends in a first direction and accommodates a deposition material in an inner space thereof, a plurality of nozzles disposed on the crucible and arranged in the first direction, a heater frame that accommodates the crucible and in which a plurality of first openings arranged in the first direction and a plurality of second openings arranged in the first direction are defined, a first heater disposed between the heater frame and the crucible, a second heater arranged together with the first heater in the first direction, a third heater arranged together with the first heater in a third direction crossing both the first direction and a second direction crossing the first direction, a fourth heater arranged together with the third heater in the first direction, a radiant heat preventing member that accommodates the heater frame, and a housing that accommodates the radiant heat preventing member. Each of the first to fourth heaters includes a first insulator, a heating element including a heater pattern disposed on the first insulator and an electrode part that is connected to one end of the heater pattern and that passes through the first openings, a second insulator that covers the electrode part, a third insulator that covers the heater pattern, a fourth insulator disposed on the heater pattern, the electrode part, and the second insulator, and a fifth insulator disposed on the fourth insulator.

The one end of the heater pattern may be closer to the nozzles than the first openings in the third direction.

The fourth insulator may include a fourth-first insulator and a fourth-second insulator. The fourth-first insulator may be disposed on the first heater and the second heater, and the fourth-second insulator may be disposed on the third heater and the fourth heater.

The linear deposition source may further include a plurality of covers movable above the second openings in the third direction.

According to an embodiment, an electronic device includes a substrate manufactured by a linear deposition source. The linear deposition source includes a crucible that extends in a first direction and accommodates a deposition material in an inner space thereof, a plurality of nozzles disposed on the crucible and arranged in the first direction, a heater frame that accommodates the crucible and in which a plurality of first openings and a plurality of second openings arranged in the first direction are defined, a plurality of heaters disposed between the heater frame and the crucible, a radiant heat preventing member that accommodates the heater frame, and a housing that accommodates the radiant heat preventing member. Each of the heaters includes a first insulator, a heating element including a heater pattern disposed on the first insulator and an electrode part that is connected to one end of the heater pattern and that passes through the first openings, a second insulator that covers the electrode part, and a third insulator that covers the heater pattern.

### BRIEF DESCRIPTION OF THE DRAWINGS

The above and other features of the present disclosure will become apparent by describing in detail embodiments thereof with reference to the accompanying drawings.

FIG. 1 is a sectional view of a deposition device according to an embodiment of the present disclosure.

FIG. 2 is a perspective view of a linear deposition source according to an embodiment of the present disclosure.

FIG. 3 is a sectional view of the linear deposition source taken along line I-I’ illustrated in FIG. 2.

FIG. 4 is a schematic perspective view of a heater frame and heaters according to an embodiment of the present disclosure.

FIG. 5 is a disassembled perspective view of a first heater according to an embodiment of the present disclosure.

FIG. 6 is an enlarged view of portion AA of FIG. 4.

FIG. 7 is an enlarged view of portion AA of FIG. 4.

FIG. 8 is a sectional view of portion AA of FIG. 4 as viewed in a third direction.

FIG. 9 is a perspective view illustrating a portion of the heater frame according to an embodiment of the present disclosure.

FIG. 10 is a perspective view illustrating the heater frame and some of the heaters according to an embodiment of the present disclosure.

FIG. 11 is a block diagram of an electronic device according to an embodiment of the present disclosure.

FIG. 12 illustrates schematic views of electronic devices according to embodiments of the present disclosure.

FIG. 13 is a plan view of a display panel including a substrate manufactured using the linear deposition source illustrated in FIG. 1.

FIG. 14 is a view illustrating a cross-section of one pixel illustrated in FIG. 13.

FIG. 15 is a view for explaining a process using the linear deposition source.

### DETAILED DESCRIPTION

In this specification, when a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as first, second, and the like may be used to describe various components, but the components should not be limited by the terms. The terms may be used only for distinguishing one component, part, area, layer, or portion from other components, parts, areas, layers, or portions. For example, without departing the scope and scope of the present disclosure, a first component, a first part, a first area, a first layer, or a first portion may be referred to as a second component, a second part, a second area, a second layer, or a second portion, and similarly, the second component, the second part, the second area, the second layer, or the second portion may also be referred to as the first component, the first part, the first area, the first layer, or the first portion. The terms of a singular form may include plural forms unless otherwise specified.

In addition, terms such as “below”, “under”, “above”, and “over” are used to describe a relationship between components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Hereinafter, embodiments of the present disclosure will be described with reference to the accompanying drawings.

A point-type deposition source may be used as a deposition source that deposits the metallic material. The point-type deposition source has a form in which a plurality of crucibles, in each of which an evaporation material is stored, are arranged. Due to a small capacity for the evaporation material, it is difficult to continuously operate the point-type deposition source for a long time. Since the point-type deposition source individually controls deposition sources, a control method is complex, which causes a deterioration in the efficiency of a deposition process. Furthermore, a separate film thickness compensation plate may be used to form a uniform film on the substrate.

To solve the problems of the point-type deposition source, a linear deposition source extending in one direction may be used. However, the linear deposition source in an extended form may have low thermal stability in a high-temperature environment or may experience a temperature deviation.

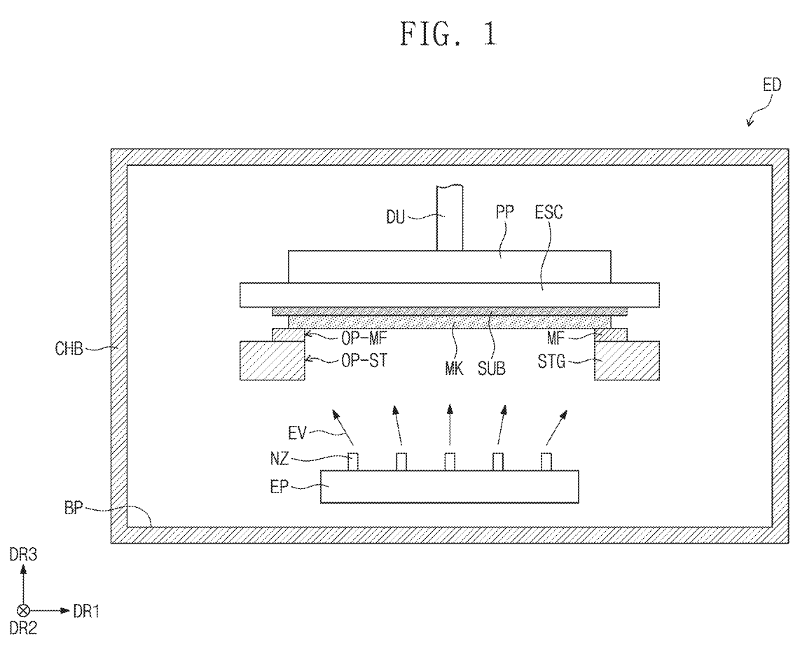

FIG. 1 is a sectional view of a deposition device according to an embodiment of the present disclosure.

Referring to FIG. 1, the deposition device ED may include a chamber CHB, a plurality of nozzles NZ, and a linear deposition source EP. The chamber CHB may provide an inner space. The chamber CHB may form a sealed space and may set a deposition condition to vacuum. The chamber CHB may include at least one gate (not shown). The chamber CHB may be opened or closed through the gate. A substrate SUB may enter or exit the chamber CHB through the gate of the chamber CHB.

The chamber CHB may include a bottom surface BP, a ceiling surface, and sidewalls. The bottom surface BP of the chamber CHB may be parallel to a plane defined by a first direction DR1 and a second direction DR2. The normal direction of the bottom surface BP of the chamber CHB may be parallel to a third direction DR3.

A fixing member PP may be disposed inside the chamber CHB and may face the linear deposition source EP in the third direction DR3. The fixing member PP may bring the substrate SUB into close contact with a mask MK. The fixing member PP may include magnetic materials for bringing the mask MK and the substrate SUB into close contact with each other. For example, the magnetic materials may generate a magnetic force to fix the mask MK, and the substrate SUB disposed between the mask MK and the fixing member PP may be brought into close contact with the mask MK. However, without being limited thereto, the fixing member PP may include a jig or a robot arm that holds the mask MK.

A driving unit DU may be coupled to the upper surface of the fixing member PP. The driving unit DU may have a cylindrical shape extending in the third direction DR3. However, without being limited thereto, the driving unit DU may have various shapes. The driving unit DU may reciprocate in the third direction DR3 to reciprocate the fixing member PP in the third direction DR3.

The substrate SUB may be disposed between the mask MK and the fixing member PP. The substrate SUB may be an object on which a deposition material is deposited. The substrate SUB may include a support substrate and a synthetic resin material disposed on the support substrate.

An electrostatic chuck ESC may be disposed between the substrate SUB and the fixing member PP. The electrostatic chuck ESC may form an electrostatic force using an electrostatic induction phenomenon. The electrostatic chuck ESC may perform chucking or dechucking of the substrate SUB through the electrostatic force. The electrostatic chuck ESC may have a shape corresponding to a portion of a quadrangle.

Although not illustrated, the electrostatic chuck ESC may be reciprocated in the third direction DR3 by an external motor. Accordingly, the electrostatic chuck ESC may be moved away from or toward the substrate SUB.

A mask frame MF may be disposed under the substrate SUB. The mask frame MF may have a quadrangular frame shape. A frame opening OP-MF may be defined in the mask frame MF having the quadrangular frame shape. The frame opening OP-MF may have a quadrangular shape.

The mask frame MF may have a certain rigidity. For example, the mask frame MF may include a metallic material such as stainless steel (SUS), Invar, nickel (Ni), or cobalt (Co).

The mask MK may be disposed between the mask frame MF and the substrate SUB. Opposite sides of the mask MK may be connected to the mask frame MF. The mask MK may be stretched to cover the frame opening OP-MF. For example, the mask MK may be stretched in the first direction DR1 by a force acting in the first direction DR1 and the direction opposite to the first direction DR1. The stretched mask MK may be connected to the mask frame MF by laser welding.

The mask MK may include a metal. For example, the mask MK may be defined as fine metal masks.

The linear deposition source EP may be disposed inside the chamber CHB and may face the fixing member PP in the third direction DR3. The linear deposition source EP may include a storage space in which a deposition material EV is accommodated and at least one nozzle NZ.

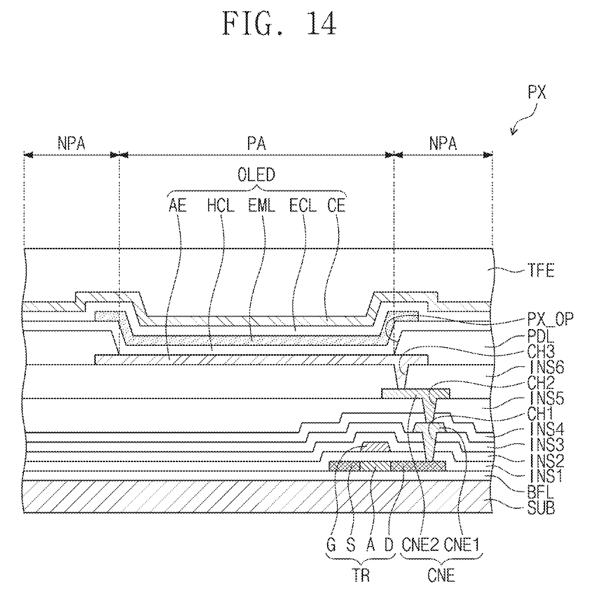

The deposition material EV may include an inorganic material, a metal, or an organic material capable of sublimation or vaporization. For example, the deposition material EV may include an organic luminescent material for forming a light emitting layer EML (refer to FIG. 14). The sublimated or vaporized deposition material EV may be jetted toward the substrate SUB through the nozzle NZ. The deposition material EV may pass through mask openings OP-MK of the mask MK and may be patterned and deposited on the substrate SUB.

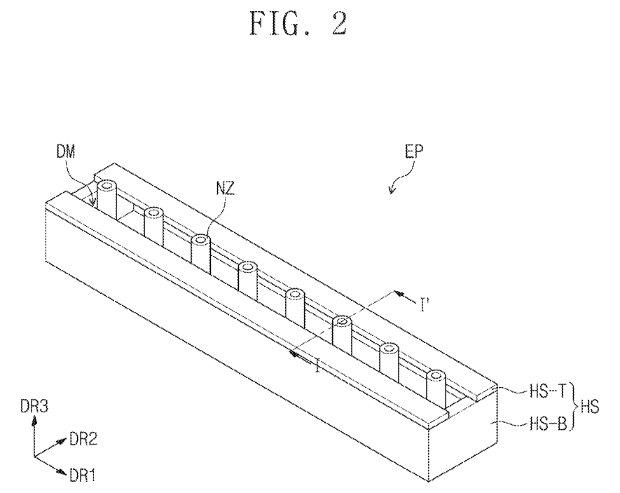

FIG. 2 is a perspective view of the linear deposition source according to an embodiment of the present disclosure.

Referring to FIG. 2, the linear deposition source EP may be a device that is included in the deposition device ED (refer to FIG. 1) and that jets the deposition material EV (refer to FIG. 1) through the plurality of nozzles NZ. In this embodiment, the linear deposition source EP is illustrated in a shape extending in the first direction DR1. The linear deposition source EP may include a housing HS and a deposition module DM.

The deposition module DM may be a module that stores and provides the deposition material EV. The deposition module DM may provide the deposition material EV by heating the stored deposition material EV and jetting the deposition material EV toward the substrate SUB (refer to FIG. 1) on which a deposition film is desired to be formed. The deposition module DM may be accommodated in the housing HS.

The deposition module DM may include the plurality of nozzles NZ. The deposition material EV may be jetted to the outside of the deposition module DM.

The deposition material EV may be jetted in the third direction DR3 through the nozzles NZ.

The nozzles NZ may be arranged in one direction. FIG. 2 illustrates the nozzles NZ arranged in the first direction DR1. The nozzles NZ may be arranged at equal intervals. However, without being limited thereto, the intervals between the nozzles NZ may vary depending on the deposition material EV, the thickness of the deposition film to be formed, and the shape and size of the substrate SUB.

Although eight nozzles NZ disposed in the housing HS are illustrated in FIG. 2, this is illustrative, and the number and arrangement of nozzles NZ included in the linear deposition source EP may vary.

The housing HS may form the exterior of the linear deposition source EP. The housing HS may extend in one direction. FIG. 2 illustrates the housing HS extending in the first direction DR1.

The housing HS may include a main body HS-B having an empty space inside. The main body HS-B may accommodate the deposition module DM in the empty space inside to protect the deposition module DM. The main body HS-B may expose the plurality of nozzles NZ in the upward direction.

The housing HS may further include top plates HS-T that are disposed on the main body HS-B and that cover partial regions of an exposed upper portion of the main body HS-B. FIG. 2 illustrates the top plates HS-T that are spaced apart from each other at a certain interval in the second direction DR2 and that expose the nozzles NZ through the spacing between the top plates HS-T. However, the top plates HS-T are not limited to any one embodiment as long as the top plates HS-T are capable of covering the partial regions of the upper portion of the main body HS-B while exposing the nozzles NZ. For example, the top plates HS-T may be integrally formed with each other to cover substantially the entire upper portion of the main body HS-B and may have a shape in which openings are defined to overlap the nozzles. Meanwhile, the top plates HS-T may be omitted.

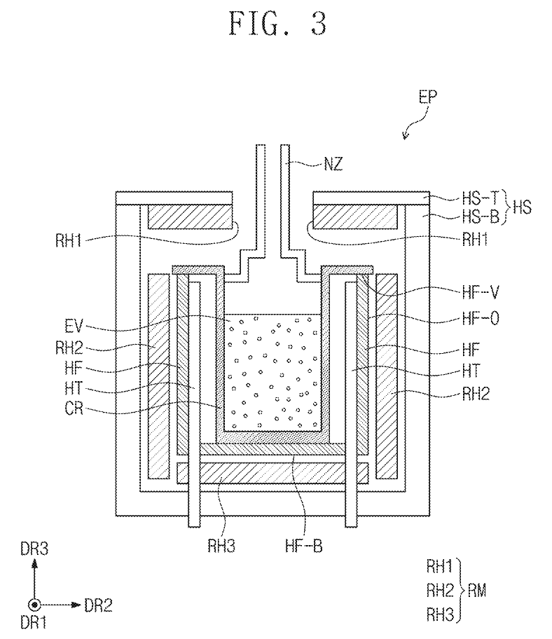

FIG. 3 is a sectional view of the linear deposition source EP taken along line I-I’ illustrated in FIG. 2.

Referring to FIG. 3, the linear deposition source EP may include a crucible CR, the nozzles NZ, a heater frame HF, a plurality of heaters HT, a radiant heat preventing member RM, and the housing HS accommodating the radiant heat preventing member RM.

The crucible CR may be open at an upper side thereof and may include an empty space inside. The crucible CR may accommodate the deposition material EV in the empty space. The deposition material EV may be a material capable of being vaporized by heat. For example, the deposition material EV may be an inorganic material or a metallic material.

The crucible CR may be a linear crucible extending in the first direction DR1. The linear crucible may accommodate a larger amount of deposition material when compared to a point-type crucible in the related art. Accordingly, the continuous operating time of the deposition device including the deposition source of the present disclosure may be increased, and the equipment utilization rate may be improved.

The crucible CR may include a material capable of being used without deformation even at high temperature. For example, the crucible CR may include a metallic material, such as molybdendum-lanthanum (Mo-La), tungsten (W), titanium-zirconium-molybdendum (TZM) alloy, or tantalum (Ta), graphite, or a carbon composite. However, the material of the crucible CR is not limited thereto.

The plurality of nozzles NZ may be disposed on the crucible CR. The nozzles NZ may be integrally formed. The nozzles NZ may be arranged in the first direction DR1. The above description may be similarly or identically applied to the nozzles NZ.

The nozzles NZ may include a material capable of being used without deformation even at high temperature. For example, the nozzles NZ may include a metallic material, such as molybdendum-lanthanum (Mo-La), tungsten (W), titanium-zirconium-molybdendum (TZM) alloy, or tantalum (Ta), graphite, or a carbon composite. However, the material of the nozzles NZ is not limited thereto.

The nozzles NZ may include the same material as the crucible CR. However, without being limited thereto, the nozzles NZ may include a material different from the material of the crucible CR.

The heater frame HF may accommodate the crucible CR. The crucible CR may be disposed inside the heater frame HF. The heater frame HF may be open at an upper side thereof and may include an empty space inside. The heater frame HF may be spaced apart from the crucible CR and may surround the side surface and the lower surface of the crucible CR.

The heaters HT may provide heat to heat the crucible CR. The heaters HT may be disposed in the separation space between the heater frame HF and the crucible CR. The heaters HT may be supported by the inner surface of the heater frame HF. The heaters HT may be disposed on the side surface and/or the lower surface of the crucible CR to at least partially surround the crucible CR.

The heaters HT may heat the crucible CR. The deposition material EV accommodated in the heated crucible CR may be evaporated and deposited on the substrate SUB (refer to FIG. 1). For example, the heaters HT may heat the crucible CR to a temperature of substantially 1000 degrees Celsius or more, specifically, a temperature of substantially 1200 degrees Celsius or more.

The radiant heat preventing member RM may block heat loss or may block dissipation of heat to the outside of the linear deposition source EP. The radiant heat preventing member RM may be disposed between the heater frame HF and the housing HS. The radiant heat preventing member RM may accommodate the heater frame HF.

The radiant heat preventing member RM may be disposed on the upper surface, the side surface, and the lower surface of the heater frame HF and may block radiant heat dissipated in the upward, lateral, and downward directions from the heater frame HF.

The radiant heat preventing member RM may include a first radiant heat preventing part RH1 disposed on the upper surface HF-V of the heater frame HF, a second radiant heat preventing part RH2 disposed on the outside surface HF-O of the heater frame HF, and a third radiant heat preventing part RH3 disposed on the lower surface HF-B of the heater frame HF. The radiant heat preventing member RM may include a plurality of reflectors (not shown).

Some of the first to third radiant heat preventing parts RH1, RH2, and RH3 may include a single-body carbon composite. For example, the second radiant heat preventing part RH2 and the third radiant heat preventing part RH3 may include a plurality of reflectors, and the first radiant heat preventing part RH1 may be a single body including a carbon composite. However, without being limited thereto, some or all of the first to third radiant heat preventing parts RH1, RH2, and RH3 may include a plurality of reflectors. The carbon composite may not be easily deformed at high temperature due to its excellent heat resistance and may block heat loss due to its low thermal conductivity.

Meanwhile, although not illustrated, the heater frame HF may further include a temperature sensing device. The temperature sensing device may measure the temperature of the crucible CR by region. By referring to the temperature measured by the temperature sensing device, the temperatures of the heaters HT may be controlled to make the overall temperature of the crucible CR uniform.

Although not illustrated, the linear deposition source EP may further include a cooling device. The cooling device may be disposed on the housing HS. The cooling device may include a cooling pipe through which cooling water flows. The cooling device may include a cooling bracket that covers the outer surface of the cooling pipe. A refrigerant or cooling water may be circulated in the cooling pipe. The cooling device may cool heat radiated upward from the linear deposition source EP and may reduce the amount of heat transferred to the substrate SUB (refer to FIG. 1) disposed over the linear deposition source EP. The radiant heat preventing member RM may make contact with the cooling device.

Since a point-type deposition source in the related art has a limitation in deposition area, a form in which a plurality of point-type deposition sources are arranged has to be used to form the deposition film on the substrate SUB. In this case, the point-type deposition sources need to be individually controlled so that it may be difficult to manage a process, and due to a deposition deviation between the deposition sources, it may be difficult to form a deposition film having a uniform thickness.

The linear deposition source EP of the present disclosure may include the plurality of nozzles NZ disposed on the crucible CR extending in one direction, thereby reducing a deposition deviation and easily forming a deposition film having a substantially uniform thickness on the substrate SUB. In addition, when compared to the point-type deposition sources, the linear deposition source EP may increase the efficiency in using the deposition material EV, thereby reducing material costs.

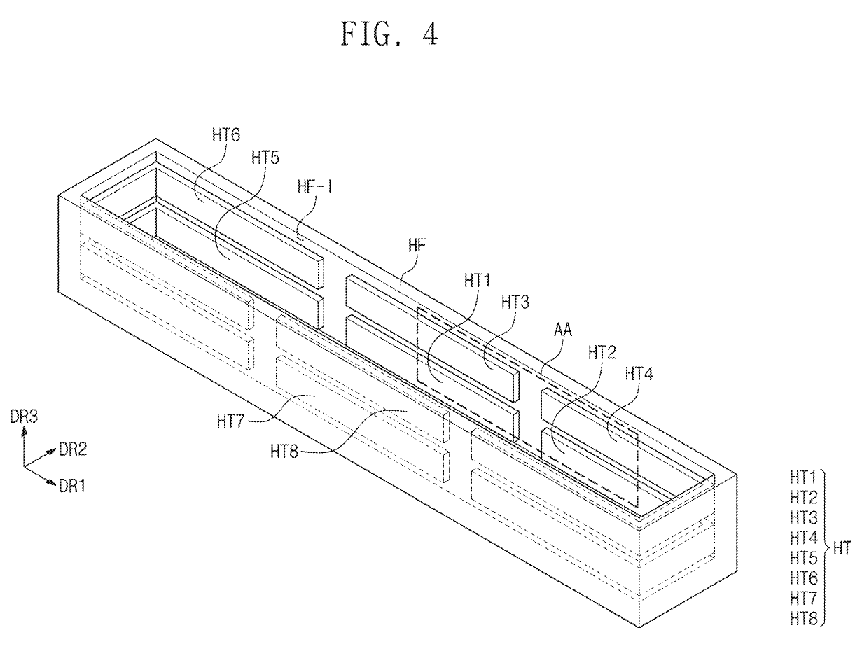

FIG. 4 is a schematic perspective view of the heater frame and the heaters according to an embodiment of the present disclosure.

Referring to FIG. 4, the heaters HT may be disposed along the inside surface HF-I of the heater frame HF. The heaters HT may be independently controlled. The heaters HT may surround the periphery of the crucible CR (refer to FIG. 3).

The heaters HT may include a first heater HT1, a second heater HT2, a third heater HT3, a fourth heater HT4, a fifth heater HT5, a sixth heater HT6, a seventh heater HT7, and an eighth heater HT8. In an embodiment of the present disclosure, the first to eighth heaters HT1 to HT8 are representatively illustrated. However, the number and arrangement of heaters HT is not limited thereto as long as the heaters HT are capable of heating the crucible CR.

The second heater HT2 may be arranged together with the first heater HT1 in the first direction DR1. Alternatively, the second heater HT2 may be arranged together with the seventh heater HT7 in the first direction DR1. The third heater HT3 may be arranged together with the first heater HT1 in the third direction DR3.

The fourth heater HT4 may be arranged together with the third heater HT3 in the first direction DR1. Alternatively, the fourth heater HT4 may be arranged together with the eighth heater HT8 in the first direction DR1.

The fifth heater HT5 may be arranged together with the first heater HT1 in the first direction DR1. Alternatively, the fifth heater HT5 may be arranged together with the seventh heater HT7 in the first direction DR1. The sixth heater HT6 may be arranged together with the third heater HT3 in the first direction DR1. Alternatively, the sixth heater HT6 may be arranged together with the eighth heater HT8 in the first direction DR1.

The seventh heater HT7 may be arranged together with the first heater HT1 in the second direction DR2. The eighth heater HT8 may be arranged together with the third heater HT3 in the second direction DR2.

The first to eighth heaters HT1 to HT8 may be independent heaters HT arranged along the inside surface HF-I of the heater frame HF. For example, one side of the first heater HT1 may be disposed adjacent to the second heater HT2, and an opposite side of the first heater HT1 may be disposed adjacent to the fifth heater HT5. The first heater HT1 and the second heater HT2 may be spaced apart from the seventh heater HT7 and the eighth heater HT8 in a direction parallel to the second direction DR2 with the crucible CR (refer to FIG. 3) therebetween.

The heaters HT may have a shape corresponding to the shape of the inside surface HF-I of the heater frame HF on which the heaters HT are disposed. For example, the second heater HT2, the fourth heater HT4, the fifth heater HT5, and the sixth heater HT6 may be heaters having the shape of a bent plate, and the first heater HT1, the third heater HT3, the seventh heater HT7, and the eighth heater HT8 may be heaters having the shape of a flat plate.

The heaters HT may be independently controlled. Accordingly, the temperatures of the heaters HT may be differently controlled, a temperature deviation in the heater frame HF may be reduced, and uniform heating may be performed. The number of heaters HT and the positions thereof may vary depending on the structure of the heater frame HF and the size of the crucible CR.

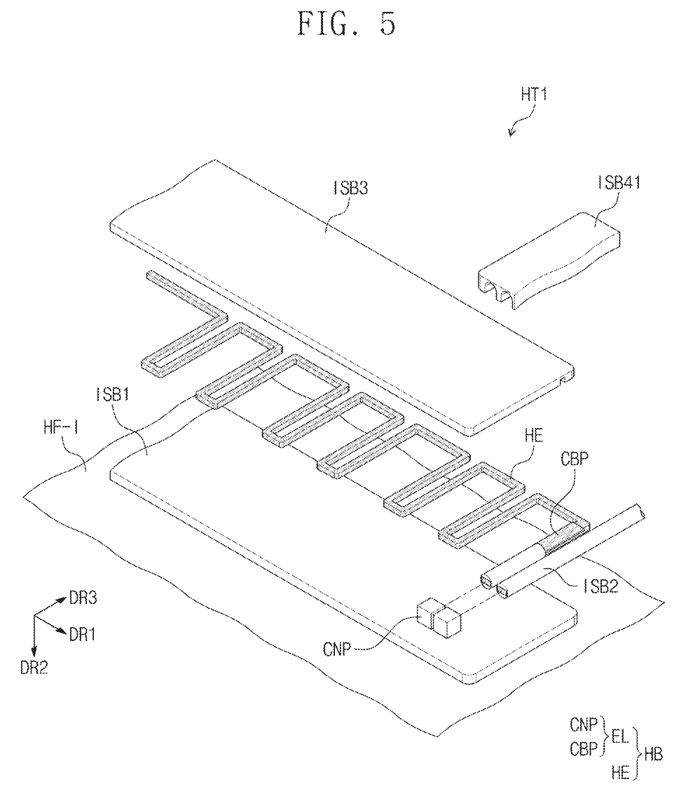

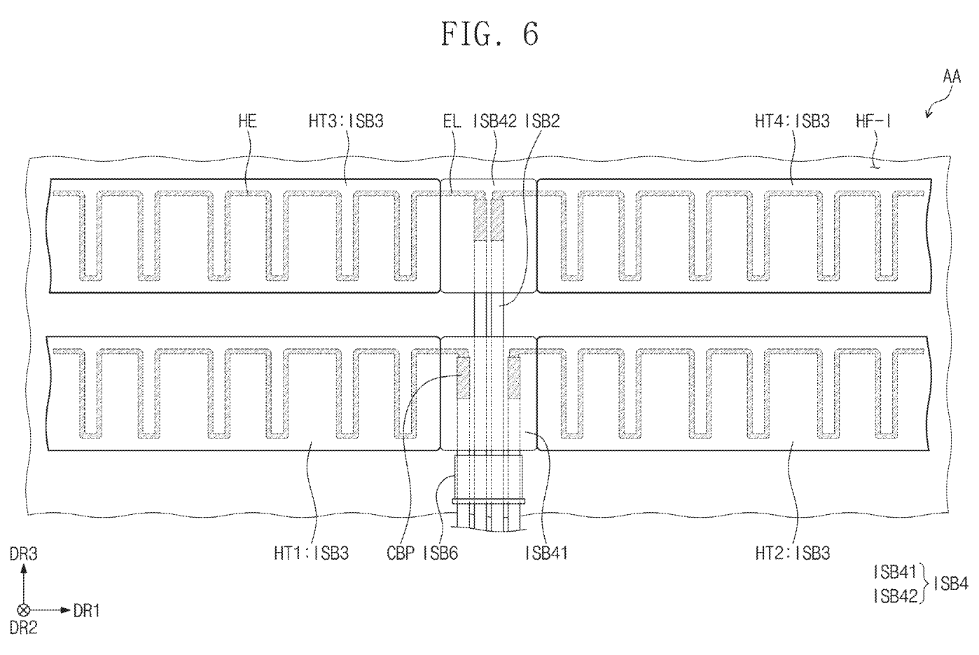

FIG. 5 is a disassembled perspective view of the first heater H1 according to an embodiment of the present disclosure. For convenience of description, the first heater HT1 will be described as an example. However, the description of the first heater HT1 may be similarly or identically applied to the second to eighth heaters HT2 to HT8. Description of a fourth-first insulator ISB41 will be given below with reference to FIG. 6.

Referring to FIG. 5, the first heater HT1 may include a first insulator ISB1, a heating element HB, a second insulator ISB2, and a third insulator ISB3.

The first insulator ISB1 may be disposed on the inside surface HF-I of the heater frame HF. The first insulator ISB1 may be formed in a plate shape.

The heating element HB may include a heater pattern HE and an electrode part EL.

The heater pattern HE may be disposed on the first insulator ISB1. The heater pattern HE may be a heating coil. Although the heater pattern HE is illustrated as having a meandering shape in this specification, the heater pattern HE is not limited to any one shape as long as the heater pattern HE is a heating means capable of generating heat.

The heater pattern HE may include a metallic material having high heat resistance. For example, the heater pattern HE may include Ta, Mo, or W, but the material of the heater pattern HE is not limited thereto.

The electrode part EL may be connected to one end of the heater pattern HE. For example, the electrode part EL may include a connecting part CNP and a fastening part CBP. The connecting part CNP may connect an external electrode (not illustrated) disposed outside the housing HS (refer to FIG. 3) and the heater pattern HE. The connecting part CNP may be connected to an opposite end of the heater pattern HE and may transfer power applied from the outside to the heater pattern HE. The connecting part CNP may pass through the lower surface of the heater frame HF (refer to FIG. 4) and the lower surface of the housing HS and may be exposed to the outside from the lower surface of the housing HS. The connecting part CNP may include a metallic material.

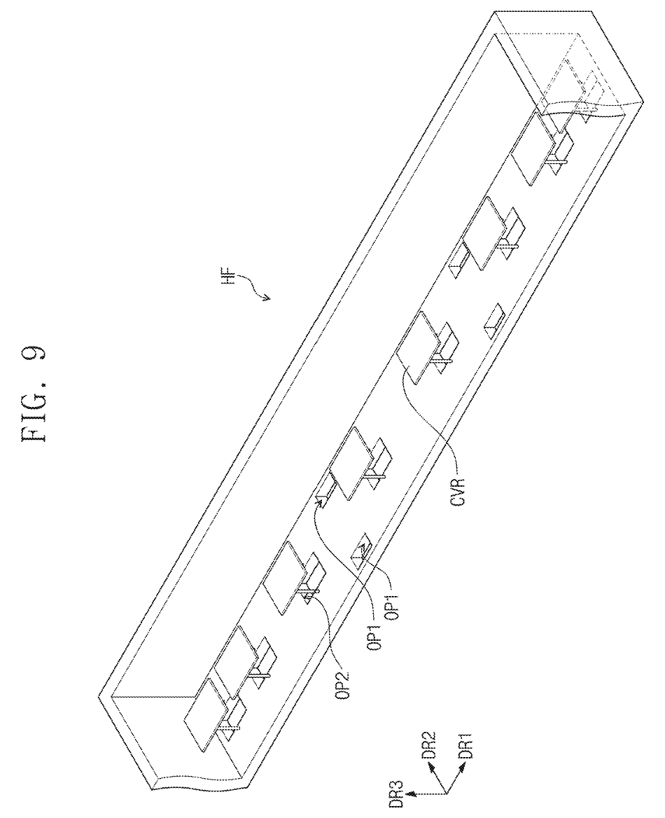

The fastening part CBP may be connected to the one end of the heater pattern HE. The one end of the heater pattern HE may be closer to the nozzles NZ (refer to FIG. 3) than first openings OP1 (refer to FIG. 9) in the third direction DR3 crossing both the first direction DR1 and the second direction DR2. The fastening part CBP may be connected to the heater pattern HE at the one end of the heater pattern HE (e.g., at the position where the heater pattern HE is farthest in the third direction DR3) when the heater pattern HE extends in a meandering shape in a direction parallel to the third direction DR3. The fastening part CBP may be connected to the farthest position in the third direction DR3 among the positions where the heater pattern HE extends in the third direction DR3.

The fastening part CBP may include a connecting member (not illustrated) that connects the heater pattern HE and the connecting part CNP. Since the fastening part CBP includes the connecting member, the electrode part EL may be easily attached to the heater pattern HE and detached from the heater pattern HE. Since the electrode part EL is attached to and detached from the heater pattern HE through the connecting member, the electrode part EL may be replaced when the deposition material EV (refer to FIG. 3) is condensed around the electrode part EL. For example, the connecting member may be a bolt or other suitable fastener.

The connecting part CNP may be exposed to the outside of the housing HS through the first openings OP1 (refer to FIG. 9) of the heater frame HF so as to be connected with the external electrode. Accordingly, the electrode part EL may have a relatively lower temperature than other components of the first heater HT1. Due to the relatively lower temperature, the deposition material EV may be condensed around the electrode part EL.

In this case, the fastening part CBP may be located at the one end of the heater pattern HE and may be spaced apart from the first openings OP1 in the third direction DR3. Since the fastening part CBP is spaced apart from the first openings OP1, a decrease in the temperature of the fastening part CBP due to the low temperature outside the housing HS may be substantially prevented or reduced. That is, the temperature of the electrode part EL may be raised.

The second insulator ISB2 may cover the electrode part EL. The second insulator ISB2 may have a pipe shape. The electrode part EL may be disposed inside the second insulator ISB2. The second insulator ISB2 may protect the electrode part EL. The deposition material EV may deviate from an evaporation path, may flow into the heaters HT, and may contaminate the electrode part EL to cause a short-circuit problem, but the second insulator ISB2 may prevent this problem.

The second insulator ISB2 may include a material that does not react with the electrode part EL at high temperature. For example, the second insulator ISB2 may include boron nitride (BN), pyrolytic boron nitride (pBN), or aluminum nitride (AlN). The description of the second insulator ISB2 may be identically applied to the first to sixth insulators ISB1 to ISB6.

The third insulator ISB3 may cover the heater pattern HE. The heater pattern HE may be disposed between the first insulator ISB1 and the third insulator ISB3.

FIG. 6 is an enlarged view of portion AA of FIG. 4.

Referring to FIG. 6, the linear deposition source EP (refer to FIG. 3) may further include the fourth insulator ISB4 and the sixth insulator ISB6. The fourth insulator ISB4 may include the fourth-first insulator ISB41 and the fourth-second insulator ISB42.

The fourth-first insulator ISB41 may be disposed on the first heater HT1 and the second heater HT2. The fourth-first insulator ISB41 may be disposed on the heater pattern HE, the electrode part EL, and the second insulator ISB2. The fourth- first insulator ISB41 may overlap the electrode part EL of the first heater HT1 and the electrode part of the second heater HT2 when viewed in the second direction DR2. The fourth-first insulator ISB41 may be disposed on the electrode part EL to prevent the electrode part EL from being exposed to the air on the inside surface HF-I of the heater frame HF. In addition, the fourth-first insulator ISB41 may cover the second insulator ISB2.

On the first heater HT1 and the second heater HT2, the fourth-first insulator ISB41 may be disposed on the electrode part EL and the second insulator ISB2 to form a local stack structure of an insulator. The fourth-first insulator ISB41 may be disposed on the second insulator ISB2 to improve a thermal insulation effect of the second insulator ISB2. Due to the local stack structure of the insulator, the thermal insulation performance of the electrode part EL may be improved. As described above with reference to FIG. 5, the temperature around the electrode part EL may be lower than the temperature of the first heater HT1 or the second heater HT2. Since the temperature around the electrode part EL is relatively lower, the deposition material EV (refer to FIG. 3) may be condensed around the electrode part EL. The fourth-first insulator ISB41 may increase the temperature around the electrode part EL through the local stack structure of the insulator to reduce or substantially eliminate the condensation of the deposition material EV.

The fourth-second insulator ISB42 may be disposed on the third heater HT3 and the fourth heater HT4. The fourth-second insulator ISB42 may be disposed on the heater pattern HE, the electrode part EL, and the second insulator ISB2. The fourth-second insulator ISB42 may overlap the electrode part EL of the third heater HT3 and the electrode part of the fourth heater HT4 when viewed in the second direction DR2. The fourth-second insulator ISB42 may be disposed on the electrode part EL to prevent the electrode part EL from being exposed to the air on the inside surface HF-I of the heater frame HF. In addition, the fourth-second insulator ISB42 may cover the second insulator ISB2.

Likewise to the fourth-first insulator ISB41, the fourth-second insulator ISB42 may also increase the temperature around the electrode part EL through a local stack structure of an insulator to reduce or substantially eliminate the condensation of the deposition material EV.

The sixth insulator ISB6 may cover the second insulator ISB2. The sixth insulator ISB6 may be disposed under the fourth-first insulator ISB41 or the fourth-second insulator ISB42. The sixth insulator ISB6 may cover the second insulator ISB2 that passes through the fourth-first insulator ISB41 in the downward direction of the third direction DR3. The sixth insulator ISB6 may additionally cover the second insulator ISB2 to reduce or substantially eliminate the condensation of the deposition material EV (refer to FIG. 3) through a local stack structure of an insulator.

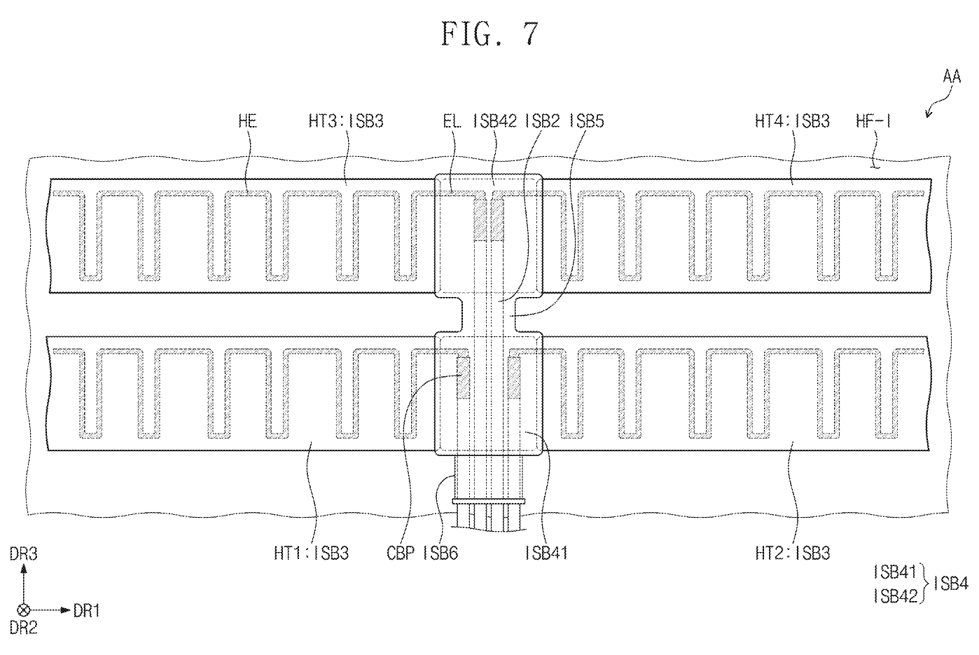

FIG. 7 is an enlarged view of portion AA of FIG. 4.

Referring to FIG. 7, the linear deposition source EP (refer to FIG. 3) may further include the fifth insulator ISB5.

The fifth insulator ISB5 may be disposed at least partially on the first heater HT1, the second heater HT2, the third heater HT3, and the fourth heater HT4. The fifth insulator ISB5 may be disposed on the fourth insulator ISB4. Although the fifth insulator ISB5 is illustrated as having the shape of “I” in this specification, the shape is not limited thereto as long as a thermal insulation effect is capable of being achieved through a local stack structure of an insulator. The fifth insulator ISB5 may be disposed on the fourth insulator ISB4 to reduce or substantially eliminate the condensation of the deposition material EV (refer to FIG. 3) through the local stack structure of the insulator.

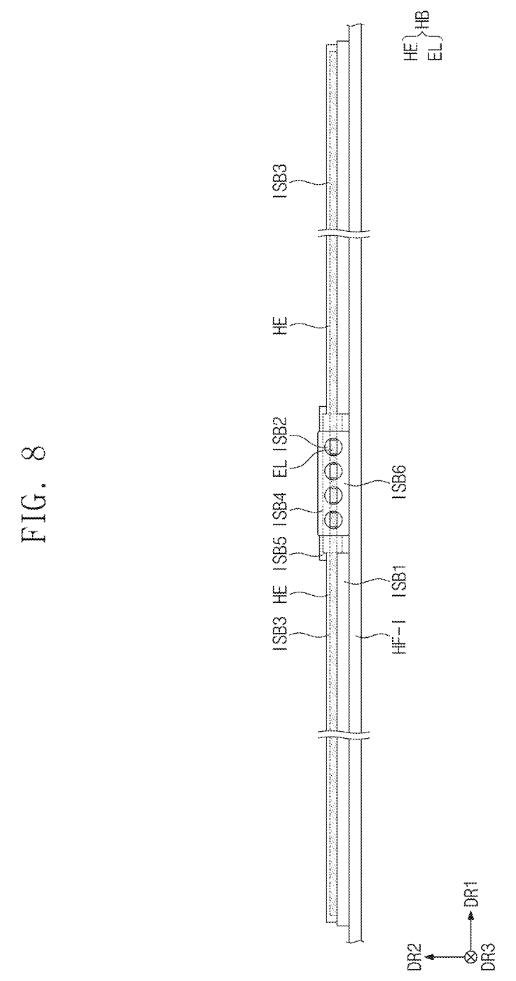

FIG. 8 is a sectional view of portion AA of FIG. 4 as viewed in the third direction.

Referring to FIG. 8, the heating element HB may be disposed on the first insulator ISB1. The second insulator ISB2 may cover the electrode part EL. The third insulator ISB3 may be disposed to cover the heating element HB on the first insulator ISB1. The fourth insulator ISB4 may be disposed between the third insulators ISB3 in a direction parallel to the first direction DR1 and may cover a portion of the heater pattern HE and the electrode part EL. The fifth insulator ISB5 may be disposed on the fourth insulator ISB4 and may cover a portion of the third insulator ISB3 and the fourth insulator ISB4. The sixth insulator ISB6 may cover the second insulator ISB2. Among the insulators, the sixth insulator ISB6 may be disposed at the lowermost position in the direction opposite to the third direction DR3.

FIG. 9 is a perspective view illustrating a portion of the heater frame according to an embodiment of the present disclosure.

Referring to FIG. 9, the heater frame HF may have the first openings OP1 and the second openings OP2 defined therein. The first openings OP1 may be arranged in the first direction DR1. The first openings OP1 may be spaced apart from each other in the second direction DR2. The second openings OP2 may be arranged in the first direction DR1. The second openings OP2 may be larger than the first openings OP1.

The heater frame HF may include a plurality of covers CVR. The covers CVR may be movable above the second openings OP2 in the third direction DR3. The flow rate of the deposition material EV moving through the second openings OP2 may be adjusted by adjusting the covers CVR disposed over the second openings OP2. The covers CVR, which are movable in the third direction DR3, may adjust the flow rate of the deposition material EV by adjusting the opening areas of the second openings OP2.

In the present disclosure, the deposition material EV may be movable through the second openings OP2. Accordingly, the condensation of the deposition material EV around the first openings OP1 may be reduced or substantially eliminated.

Although not illustrated, the linear deposition source EP (refer to FIG. 2) may further include a camera. The camera may take an image of the inside of the heater frame HF through the second openings OP2. The status of the equipment may be monitored and checked by taking, by the camera, an image of the inside of the heater frame HF. Accordingly, when the deposition material EV (refer to FIG. 3) is condensed, the condensation of the deposition material EV may be reduced or substantially prevented through proactive monitoring before the amount of condensation of the deposition material EV inside the heater frame HF is increased.

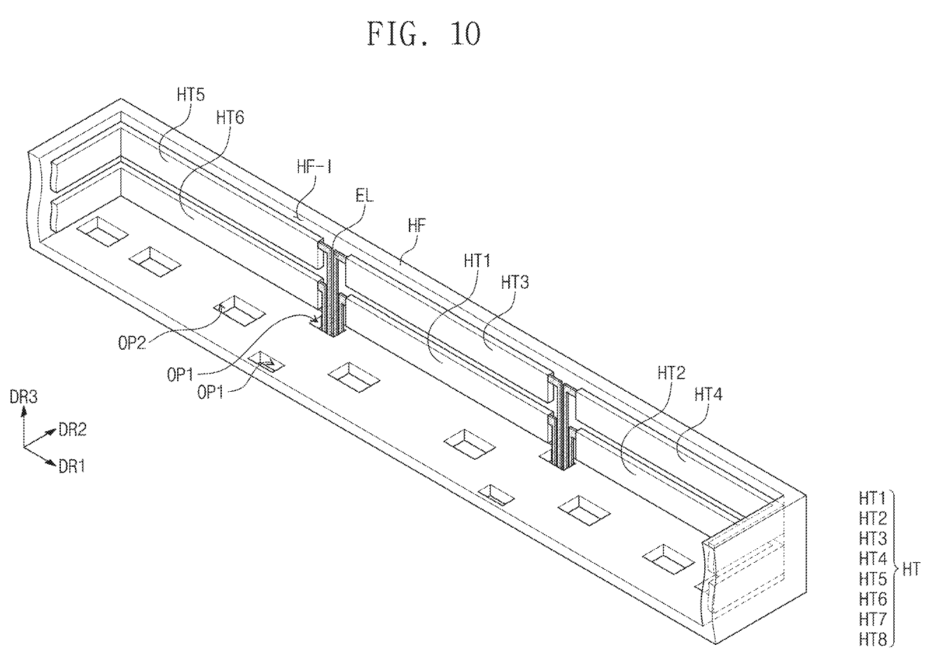

FIG. 10 is a perspective view illustrating the heater frame and some of the heaters according to an embodiment of the present disclosure. In FIG. 10, for convenience of description, the heaters HT are schematically illustrated, only the electrode part EL is illustrated, and the covers CVR are omitted.

Referring to FIG. 10, the electrode part EL may pass through the first openings OP1. Although only a portion of the electrode part EL passing through the first openings OP1 is illustrated for convenience of description, the electrode part EL may pass through all of the first openings OP1. The electrode part EL may be exposed outside the housing HS (refer to FIG. 3) for connection with the external electrode. Due to the exposure, the temperature around the first openings OP1 may be maintained at a relatively lower temperature so that the deposition material EV (refer to FIG. 3) may be condensed around the first openings OP1.

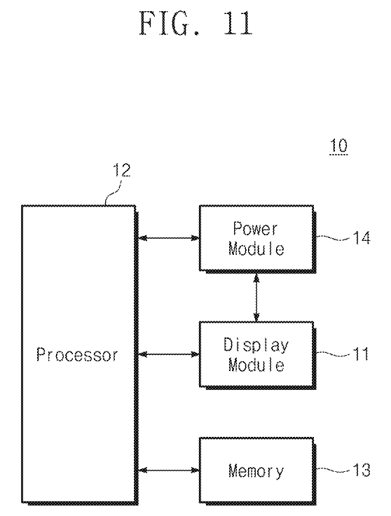

FIG. 11 is a block diagram of an electronic device according to an embodiment of the present disclosure.

Referring to FIG. 11, the electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller. The processor 12 may process an image signal and may provide the processed image signal to a display device.

Data information required for operation of the processor 12 or the display module 11 may be stored in the memory 13. When the processor 12 executes an application stored in the memory 13, an image data signal and/or an input control signal may be transferred to the display module 11, and the display module 11 may process the provided signal and may output image information through a display screen.

The power module 14 may include a power supply module such as a power adapter or a battery device and a power conversion module that converts power supplied by the power supply module and generates power required for operation of the electronic device 10.

At least one of the components of the electronic device 10 described above may be included in the display device according to the above-described embodiments. In addition, some of the separate modules functionally included in one module may be included in the display device, and the others may be provided separately from the display device. For example, the display device may include the display module 11, and the processor 12, the memory 13, and the power module 14 may be provided in the form of other devices in the electronic device 10 rather than the display device.

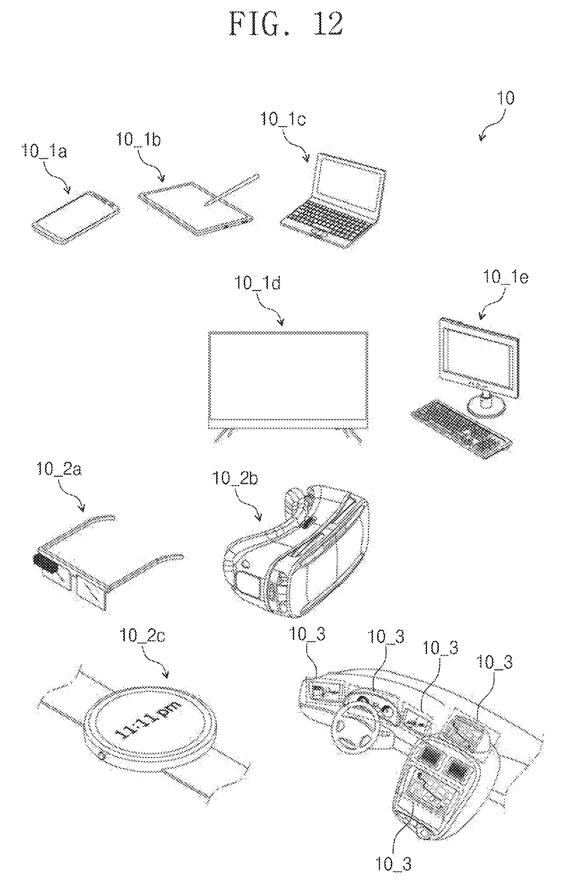

FIG. 12 illustrates schematic views of electronic devices according to embodiments of the present disclosure.

Referring to FIG. 12, various electronic devices to which display devices according to embodiments are applied may include not only electronic devices for displaying images, such as a smart phone 10_1a, a tablet PC 10_1b, a laptop computer 10_1c, a TV 10_1d, and a desk monitor 10_1e, but also wearable electronic devices including a display module, such as smart glasses 10_2a, a head mounted display 10_2b, and a smart watch 10_2c, and vehicle electronic devices 10_3 including a display module, such as center information displays (CID) disposed on an instrument panel, a center fascia, and a dashboard of a vehicle and a room mirror display. The electronic devices may include the substrate SUB (refer to FIG. 1) manufactured by the linear deposition source EP (refer to FIG. 2) according to the embodiment of the present disclosure.

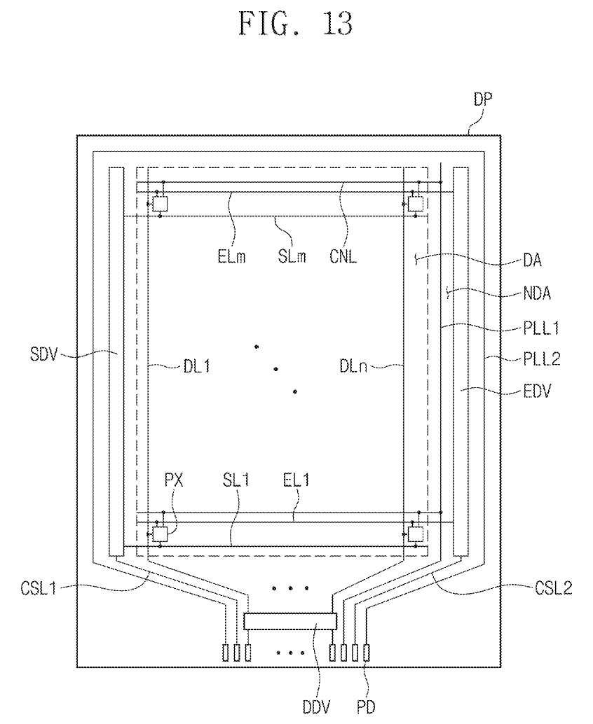

FIG. 13 is a plan view of a display panel including the substrate manufactured using the linear deposition source illustrated in FIG. 1.

The display panel DP may have a rectangular shape with short sides and long sides, but the shape of the display panel DP is not limited thereto. The display panel DP may include a display part DA and a non-display part NDA surrounding the display part DA.

The display panel DP may be an emissive display panel. The display panel DP may be an organic light emitting display panel or a quantum-dot light emitting display panel. A light emitting layer of the organic light emitting display panel may include an organic luminescent material. A light emitting layer of the quantum-dot light emitting display panel may include a quantum dot and a quantum rod. Hereinafter, it will be exemplified that the display panel DP is an organic light emitting display panel.

The display panel DP may include a plurality of pixels PX, a plurality of scan lines SL1 to SLm, a plurality of data lines DL1 to DLn, a plurality of emission lines EL1 to ELn, a first control line CSL1, a second control line CSL2, a first power line PLL1, a second power line PLL2, connecting lines CNL, and a plurality of pads PD. “m” and “n” are natural numbers.

The pixels PX may be disposed in the display part DA. A scan driver SDV and an emission driver EDV may be disposed on the non-display parts NDA adjacent to the long sides of the display panel DP. A data driver DDV may be disposed on the non-display part NDA adjacent to one of the short sides of the display panel DP. The data driver DDV may be adjacent to the lower end of the display panel DP when viewed from above a plane.

The scan lines SL1 to SLm may extend in the first direction DR1 and may be connected to the pixels PX and the scan driver SDV. The data lines DL1 to DLn may extend in the second direction DR2 and may be connected to the pixels PX and the data driver DDV. The emission lines EL1 to ELm may extend in the first direction DR1 and may be connected to the pixels PX and the emission driver EDV.

The first power line PLL1 may extend in the second direction DR2 and may be disposed in the non-display part NDA. The first power line PLL1 may be disposed between the display part DA and the emission driver EDV. However, without being limited thereto, the first power line PLL1 may be disposed between the display part DA and the scan driver SDV.

The connecting lines CNL may extend in the first direction DR1 and may be arranged in the second direction DR2. The connecting lines CNL may be connected to the first power line PLL1 and the pixels PX. A first voltage may be applied to the pixels PX through the first power line PLL1 and the connecting lines CNL connected with each other.

The second power line PLL2 may be disposed in the non-display part NDA. The second power line PLL2 may extend along the long sides of the display panel DP and the short side of the display panel DP where the data driver DDV is not disposed. The second power line PLL2 may be disposed outward of the scan driver SDV and the emission driver EDV.

Although not illustrated, the second power line PLL2 may extend toward the display part DA and may be connected to the pixels PX. A second voltage having a lower level than the first voltage may be applied to the pixels PX through the second power line PLL2.

The first control line CSL1 may be connected to the scan driver SDV and may extend toward the lower end of the display panel DP when viewed from above the plane. The second control line CSL2 may be connected to the emission driver EDV and may extend toward the lower end of the display panel DP when viewed from above the plane. The data driver DDV may be disposed between the first control line CSL1 and the second control line CSL2.

The pads PD may be disposed on the display panel DP. The pads PD may be closer to the lower end of the display panel DP than the data driver DDV. The data driver DDV, the first power line PLL1, the second power line PLL2, the first control line CSL1, and the second control line CSL2 may be connected to the pads PD. The data lines DL1 to DLn may be connected to the data driver DDV, and the data driver DDV may be connected to the pads PD corresponding to the data lines DL1 to DLn.

Unit regions corresponding to the display panel DP may be defined in the above-described substrate SUB. The unit regions may be cut after light emitting elements are formed in the unit regions. Accordingly, the display panel DP illustrated in FIG. 11 may be manufactured.

Although not illustrated, a timing controller for controlling operation of the scan driver SDV, the data driver DDV, and the emission driver EDV and a voltage generator for generating the first voltage and the second voltage may be disposed on a printed circuit board. The timing controller and the voltage generator may be connected to the corresponding pads PD through the printed circuit board.

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DL1 to DLn. The emission driver EDV may generate a plurality of emission signals, and the emission signals may be applied to the pixels PX through the emission lines EL1 to ELm.

The pixels PX may receive the data voltages in response to the scan signals. The pixels PX may display an image by emitting light having luminance corresponding to the data voltages in response to the emission signals. The light emission time of the pixels PX may be controlled by the emission signals.

The above-described lines may include the data lines DL1 to DLn. Pads connected to the above-described lines may include the pads PD illustrated in FIG. 13. The display panel DP in which the light emitting layers of the pixels PX are not formed may be defined as the above-described substrate SUB.

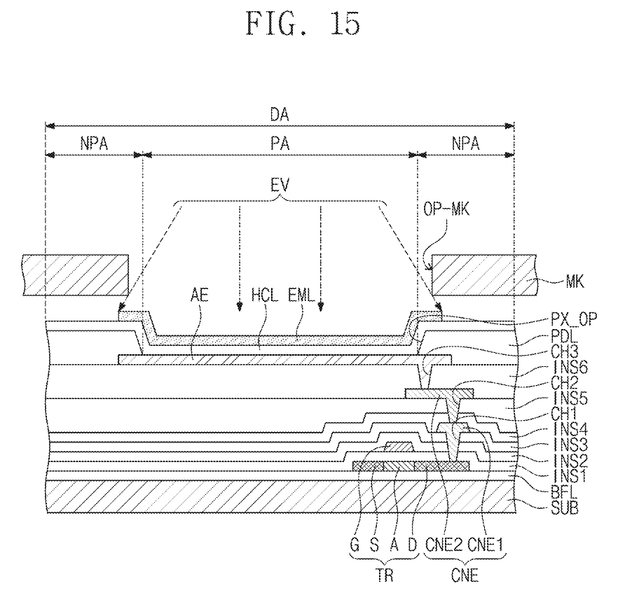

The cross-sectional structure of the substrate SUB on which the light emitting layers are not formed will be described below with reference to FIG. 15. The pads PD may be formed on the substrate SUB, and the substrate SUB may be defined as a state in which the printed circuit board is not connected.

FIG. 14 is a view illustrating a cross-section of one pixel illustrated in FIG. 13.

Referring to FIG. 14, the pixel PX may be disposed on a substrate SUB and may include a transistor TR and a light emitting element OLED. The transistors TR and the light emitting elements OLED of the pixels PX may be connected to the data lines DL1 to DLn, the first power line PLL1, and the second power line PLL2 described above.

The transistors TR and the light emitting elements OLED of the pixels PX may be connected to the pads PD of FIG. 13 through the data lines DL1 to DLn (refer to FIG. 13), the first power line PLL1 (refer to FIG. 13), and the second power line PLL2 (refer to FIG. 13).

The light emitting element OLED may include a first electrode AE, a second electrode CE, a hole control layer HCL, an electron control layer ECL, and the light emitting layer EML. The first electrode AE may be an anode electrode, and the second electrode CE may be a cathode electrode.

The transistor TR and the light emitting element OLED may be disposed on the substrate SUB. Although one transistor TR is illustrated as an example, substantially, the pixel PX may include a plurality of transistors and at least one capacitor for driving the light emitting element OLED.

The display part DA may include a light emitting part PA corresponding to the pixel PX and a non-light emitting part NPA around the light emitting part PA. The light emitting element OLED may be disposed in the light emitting part PA.

The substrate SUB may include a flexible plastic substrate. For example, the substrate SUB may include transparent polyimide (PI). A buffer layer BFL may be disposed on the substrate SUB. The buffer layer BFL may be an inorganic layer.

A semiconductor pattern may be disposed on the buffer layer BFL. The semiconductor pattern may include poly silicon. However, without being limited thereto, the semiconductor pattern may include amorphous silicon or metal oxide.

The semiconductor pattern may be doped with an N-type dopant or a P-type dopant. The semiconductor pattern may include a highly doped region and a lightly doped region. The highly doped region may have a higher conductivity than the lightly doped region and may substantially serve as a source electrode and a drain electrode of the transistor TR. The lightly doped region may substantially correspond to an active region (or, a channel) of the transistor TR.

The source S, the active region A, and the drain D of the transistor TR may be formed from the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

A connecting electrode CNE may be disposed between the transistor TR and the light emitting element OLED and may connect the transistor TR and the light emitting element OLED. The connecting electrode CNE may include a first connecting electrode CNE1 and a second connecting electrode CNE2.

The first connecting electrode CNE1 may be disposed on the third insulating layer INS3 and may be connected to the drain D through a first contact hole CH1 defined in the first to third insulating layers INS1 to INS3. A fourth insulating layer INS4 may be disposed on the first connecting electrode CNE1. A fifth insulating layer INS5 may be disposed on the fourth insulating layer INS4.

The second connecting electrode CNE2 may be disposed on the fifth insulating layer INS5. The second connecting electrode CNE2 may be connected to the first connecting electrode CNE1 through a second contact hole CH2 defined in the fifth insulating layer INS5. A sixth insulating layer INS6 may be disposed on the second connecting electrode CNE2. The first to sixth insulating layers INS1 to INS6 may be inorganic layers or organic layers.

The first electrode AE may be disposed on the sixth insulating layer INS6. The first electrode AE may be connected to the second connecting electrode CNE2 through a third contact hole CH3 defined in the sixth insulating layer INS6. A pixel defining layer PDL that exposes a certain portion of the first electrode AE may be disposed on the first electrode AE and the sixth insulating layer INS6. An opening PX_OP for exposing the certain portion of the first electrode AE may be defined in the pixel defining layer PDL.

The hole control layer HCL may be disposed on the first electrode AE and the pixel defining layer PDL. The hole control layer HCL may be commonly disposed in the light emitting part PA and the non-light emitting part NPA. The hole control layer HCL may include a hole transport layer and a hole injection layer.

The light emitting layer EML may be disposed on the hole control layer HCL. The light emitting layer EML may be disposed in the region corresponding to the opening PX_OP. The light emitting layer EML may include an organic material and/or an inorganic material. The light emitting layer EML may generate one of red light, green light, and blue light.

The electron control layer ECL may be disposed on the light emitting layer EML and the hole control layer HCL. The electron control layer ECL may be commonly disposed in the light emitting part PA and the non-light emitting part NPA. The electron control layer ECL may include an electron transport layer and an electron injection layer.

The second electrode CE may be disposed on the electron control layer ECL. The second electrode CE may be commonly disposed in the pixels PX. The layers from the buffer layer BFL to the light emitting element OLED may be defined as a pixel layer PXL.

A thin film encapsulation layer TFE may be disposed on the light emitting element OLED. The thin film encapsulation layer TFE may be disposed on the second electrode CE and may cover the pixel PX. The thin film encapsulation layer TFE may include at least two inorganic layers and an organic layer between the inorganic layers. The inorganic layers may protect the pixel PX from moisture/oxygen. The organic layer may protect the pixel PX from foreign matter such as dust particles.

The first voltage may be applied to the first electrode AE through the transistor TR, and the second voltage having a lower level than the first voltage may be applied to the second electrode CE. Holes and electrons injected into the light emitting layer EML may be combined to form excitons, and as the excitons transition to a ground state, the light emitting element OLED may emit light.

FIG. 15 is a view for explaining a process using the linear deposition source.

Referring to FIGS. 13 to 15, the layers from the substrate SUB to the layer where the hole control layer HCL is disposed may be defined as the substrate SUB. As described above, the transistor TR may be connected to the pads PD through the data lines DL1 to DLn. That is, the substrate SUB may include the data lines DL1 to DLn defined by the above-described lines and the pads PD connected to the data lines DL1 to DLn.

The mask MK may be disposed to face the substrate SUB. The mask MK may be disposed in close proximity to the substrate SUB. The deposition material EV may be provided to the substrate SUB through the mask opening OP-MK defined in the mask MK. The light emitting layer EML may be formed on the substrate SUB by the deposition material EV.

As described above, the insulator may form the local stack structure of the insulator on the heater. Due to the local stack structure of the insulator, the thermal insulation performance of the electrode part may be improved. The condensation of the deposition material may be reduced or substantially eliminated by increasing the temperature around the electrode part through the local stack structure of the insulator. In addition, the deposition material may be movable through the second openings. Accordingly, the condensation of the deposition material around the first openings may be reduced or substantially eliminated.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A linear deposition source comprising:
a crucible which extends in a first direction and accommodates a deposition material in an inner space thereof;
a plurality of nozzles disposed on the crucible and arranged in the first direction;
a heater frame in which a plurality of first openings and a plurality of second openings arranged in the first direction are defined, the heater frame accommodating the crucible;
a plurality of heaters disposed between the heater frame and the crucible;
a radiant heat preventing member which accommodates the heater frame; and
a housing which accommodates the radiant heat preventing member,
wherein each of the heaters includes:
a first insulator;
a heating element including a heater pattern disposed on the first insulator and an electrode part connected to one end of the heater pattern and passing through the plurality of first openings;
a second insulator which covers the electrode part; and
a third insulator which covers the heater pattern.

2. The linear deposition source of claim 1, wherein the electrode part includes:
a connecting part which connects an external electrode disposed outside the housing and the heater pattern; and
a fastening part connected to the one end of the heater pattern.

3. The linear deposition source of claim 2, wherein the fastening part includes a connecting member which connects the heater pattern and the connecting part.

4. The linear deposition source of claim 1, wherein the one end of the heater pattern is closer to the plurality of nozzles than the plurality of first openings in a third direction crossing both the first direction and a second direction crossing the first direction.

5. The linear deposition source of claim 1, wherein the first insulator has a plate shape,
wherein the second insulator has a pipe shape, and
wherein the third insulator has the plate shape.

6. The linear deposition source of claim 1, wherein the heaters are disposed along an inside surface of the heater frame and are independently controllable.

7. The linear deposition source of claim 1 wherein the heaters include:
a first heater;
a second heater arranged together with the first heater in the first direction;
a third heater arranged together with the first heater in a third direction crossing both the first direction and a second direction crossing the first direction; and
a fourth heater arranged together with the third heater in the first direction.

8. The linear deposition source of claim 7, further comprising:
a fifth insulator disposed on the first heater, the second heater, the third heater, and the fourth heater.

9. The linear deposition source of claim 7, further comprising:
a fourth-first insulator disposed on the first heater and the second heater; and
a fourth-second insulator disposed on the third heater and the fourth heater.

10. The linear deposition source of claim 9, wherein the fourth-first insulator and the fourth-second insulator are disposed on the heater pattern, the electrode part, and the second insulator.

11. The linear deposition source of claim 9, further comprising:
a sixth insulator which covers the second insulator and is disposed under the fourth-first insulator or the fourth-second insulator.

12. The linear deposition source of claim 1, further comprising:
a plurality of covers movable above the plurality of second openings in a third direction crossing both the first direction and a second direction crossing the first direction.

13. The linear deposition source of claim 1, further comprising:
a camera disposed outside the heater frame and taking an image of the inside of the heater frame through the plurality of second openings.

14. The linear deposition source of claim 1, further comprising:
a cooling device disposed on the housing,
wherein the cooling device includes a cooling pipe through which cooling water flows, and the radiant heat preventing member makes contact with the cooling device.

15. A linear deposition source comprising:
a crucible which extends in a first direction and accommodates a deposition material in an inner space thereof;
a plurality of nozzles disposed on the crucible and arranged in the first direction;
a heater frame in which a plurality of first openings arranged in the first direction and a plurality of second openings arranged in the first direction are defined, the heater frame accommodating the crucible;
a first heater disposed between the heater frame and the crucible;
a second heater arranged together with the first heater in the first direction;
a third heater arranged together with the first heater in a third direction crossing both the first direction and a second direction crossing the first direction;
a fourth heater arranged together with the third heater in the first direction;
a radiant heat preventing member which accommodates the heater frame; and
a housing which accommodates the radiant heat preventing member,
wherein each of the first to fourth heaters includes:
a first insulator;
a heating element including a heater pattern disposed on the first insulator and an electrode part connected to one end of the heater pattern and passing through the plurality of first openings;
a second insulator which covers the electrode part;
a third insulator which covers the heater pattern;
a fourth insulator disposed on the heater pattern, the electrode part, and the second insulator; and
a fifth insulator disposed on the fourth insulator.

16. The linear deposition source of claim 15, wherein the one end of the heater pattern is closer to the plurality of nozzles than the plurality of first openings in the third direction.

17. The linear deposition source of claim 15, wherein the fourth insulator includes a fourth-first insulator and a fourth-second insulator,
wherein the fourth-first insulator is disposed on the first heater and the second heater, and
wherein the fourth-second insulator is disposed on the third heater and the fourth heater.

18. The linear deposition source of claim 15, further comprising:
a plurality of covers movable above the plurality of second openings in the third direction.

19. An electronic device comprising:
a substrate manufactured by a linear deposition source,
wherein the linear deposition source includes:
a crucible which extends in a first direction and accommodates a deposition material in an inner space thereof;
a plurality of nozzles disposed on the crucible and arranged in the first direction;
a heater frame in which a plurality of first openings and a plurality of second openings arranged in the first direction are defined, the heater frame accommodating the crucible;
a plurality of heaters disposed between the heater frame and the crucible;
a radiant heat preventing member which accommodates the heater frame; and
a housing which accommodates the radiant heat preventing member, and
wherein each of the heaters includes:
a first insulator;
a heating element including a heater pattern disposed on the first insulator and an electrode part connected to one end of the heater pattern and passing through the plurality of first openings;
a second insulator which covers the electrode part; and
a third insulator which covers the heater pattern.

20. A method of manufacturing a substrate using a linear disposition source, the method comprising:
disposing a mask to face the substrate; and
providing a deposition material to the substrate through a mask opening defined in the mask using the linear disposition source,
wherein the linear deposition source includes:
a crucible which extends in a first direction and accommodates a deposition material in an inner space thereof;
a plurality of nozzles disposed on the crucible and arranged in the first direction;
a heater frame in which a plurality of first openings and a plurality of second openings arranged in the first direction are defined, the heater frame accommodating the crucible;
a plurality of heaters disposed between the heater frame and the crucible;
a radiant heat preventing member which accommodates the heater frame; and
a housing which accommodates the radiant heat preventing member, and
wherein each of the heaters includes:
a first insulator;
a heating element including a heater pattern disposed on the first insulator and an electrode part connected to one end of the heater pattern and passing through the plurality of first openings;
a second insulator which covers the electrode part; and
a third insulator which covers the heater pattern.
